(19) United States
(12) Patent Application Publication
(10) Pub. No.: US 2012/0322175 A1
(43) Pub. Date: Dec. 20, 2012

(54) Methods and Systems For Controlling SiIicon Rod Temperature

(75) Inventors: Gianluca Pazzaglia, Merano (IT); Matteo Fumagalli, Merano (IT); Manuel Poniz, Merano (IT)

(73) Assignee: MEMC Electronic Materials SpA, Merano (IT)

(21) Appl. No.: 13/493,285

(22) Filed: Jun. 11, 2012

Related U.S. Application Data
(60) Provisional application No. 61/496,826, filed on Jun. 14, 2011.

(51) Int. Cl. C23C 16/52; H01L 21/66

(52) U.S. Cl. 438/17; 118/712; 257/E21.521

(57) ABSTRACT

Systems and methods are provided for controlling silicon rod temperature. In one example, a method of controlling a surface temperature of at least one silicon rod in a chemical vapor deposition (CVD) reactor during a CVD process is presented. The method includes determining an electrical resistance of the at least one silicon rod, comparing the resistance to a set point to determine a difference, and controlling a power supply to control a power output coupled to the at least one silicon rod to minimize an absolute value of the difference.

### CROSS-REFERENCE TO RELATED APPLICATIONS

This application claims priority to U.S. Provisional Application No. 61/496,826 filed Jun. 14, 2011, the entire disclosure of which is hereby incorporated by reference in its entirety.

### FIELD

This disclosure generally relates to systems and methods for controlling silicon rod temperature during a deposition process and, more specifically, to controlling a silicon rod surface temperature during a deposition process by controlling the electrical current intensity through the rod.

### BACKGROUND

Ultrapure polysilicon used in the electronic and solar industry is often produced through deposition from gaseous reactants via a chemical vapor deposition (CVD) process conducted within a reactor.

One process used to produce ultrapure polycrystalline silicon in a CVD reactor is referred to as a Siemens process. Silicon filaments disposed within the reactor are used as seeds to start the process. Gaseous silicon-containing reactants flow through the reactor and deposit silicon onto the surface of the filaments, thereby forming silicon rods. The gaseous reactants (i.e., gaseous precursors) include silicon halides such as trichlorosilane mixed with a suitable carrier gas, generally hydrogen. Because trichlorosilane is kinetically stable, CVD processes are rather slow and commonly utilize relatively high temperatures to permit the deposition to occur. It is not uncommon to utilize rod surface temperature greater than 1000° C. Under such conditions the gaseous reactants decompose on the surface of the rods. Silicon is thus deposited on the rods according to the following global reaction:

SiHCl₃+H₂→Si+3HCl. [1]

The process is stopped after a layer of silicon having a predetermined thickness has been deposited on the surface of the rods. The rods are then extracted from the CVD reactor and the silicon is harvested from the rods for further processing.

During the CVD process, the surface temperature of the silicon rods typically needs to be controlled. If the surface temperature is too high, excessive silicon dust may be produced and poor silicon morphology may be generated. If the surface temperature is too low, the deposition may be slow or may not even occur.

The Siemens process employs Joule heating to achieve desired surface temperatures. Electrical energy is converted into thermal energy to heat up the silicon rods. Electrical current is provided to the reactor by a power supply that adjusts the voltage supplied across each rod in order to control the current intensity.

During the deposition process, however, the power demand of the reactor is not constant. The thermal power leaving the silicon rods increases with the deposition time as the surface area of the rod increases. Accordingly, the current through the rods is constantly adjusted in order to maintain the desired rod surface temperature.

At least one known method of controlling rod temperature utilizes a pyrometer to monitor deviation of the rod surface temperature. When the monitored temperature deviates from a desired set point, electrical intensity is adjusted to attempt to return the rod surface temperature to the desired set point. Inaccuracies in the measurement of rod surface temperature may result from poor calibration and/or incorrect installation of the pyrometer. Moreover, the rod surface temperature measurement may be affected by the presence of silicon dust inside the reaction chamber or deposited on the surface of the sight glass where the pyrometer is installed. The intensity of emitted radiation from the rods is attenuated by the silicon dust. Therefore, built up silicon powder generally causes the measured temperature to underestimate the actual rod surface temperature. The current through the rods is commonly increased to raise the surface temperature, causing the rod surface temperature to be higher than actually desired and causing production of even more silicon dust. This additional dust may cause the monitored temperature to be even more inaccurate. This cycle of underestimating rod surface temperature and increasing current may result in rod surface temperatures much greater than desired. These high temperatures can result in a popcorn style morphology and, in some cases, melting of the silicon rods.

Some known techniques to avoid dust formation avoid high trichlorosilane to hydrogen molar ratios and maintain the gas bulk temperature below certain values by using low flow rates, enhancing reactor cooling, and/or adopting lower rods surface temperature. Such measures, however, generally slow down the deposition rate and increase the energy consumption of the reactor.

This Background section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF SUMMARY

One aspect of the present disclosure is a method of controlling a surface temperature of at least one silicon rod in a chemical vapor deposition (CVD) reactor during a CVD process. The method includes determining an electrical resistance of the at least one silicon rod and comparing the resistance to a set point to determine a difference. The method includes controlling a power supply coupled to the at least one silicon rod to minimize an absolute value of the difference according to a feedback process control scheme.

Another aspect of the present disclosure is a system including a chemical vapor deposition (CVD) reactor, a plurality of groups of silicon rods coupled within the CVD reactor, a power supply coupled to provide power to the plurality of pairs of silicon rods, and a controller. The controller is configured to determine a first resistance of a first group of silicon rods of the plurality of groups of silicon rods, compare the first resistance to a set point to determine a first difference, and control the power supply to minimize an absolute value of the first difference.

Yet another aspect of the present disclosure is a method of controlling a chemical vapor deposition (CVD) process in a reactor. The method includes controlling an amount of power provided to a group of silicon rods in the reactor as a function of an amount of reactant input to the reactor during the CVD process and an electrical resistance of the group of silicon rods.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1 is a block diagram of an exemplary system including a power supply and a reactor; and

FIG. 2 is a graph plotting resistance of a silicon rod as a function of amount of trichlorosilane used in a chemical vapor deposition process.

Like reference symbols in the various drawings indicate like elements.

### DETAILED DESCRIPTION

The embodiments described herein generally relate to systems and methods for controlling rod surface temperature in a polysilicon reactor. More specifically, embodiments described herein relate to controlling a silicon rod surface temperature by controlling electrical current through the rod.

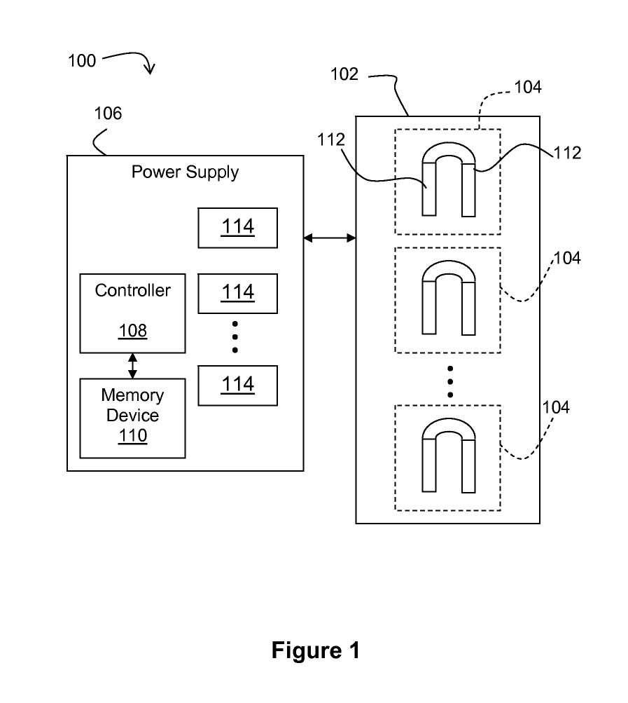

A block diagram of an exemplary system, generally indicated by reference numeral 100, according to the present disclosure is illustrated in FIG. 1. System 100 includes a reactor 102 having a plurality of silicon rod groups 104. A power supply 106 is coupled to reactor 102. More particularly, power supply 106 is coupled to silicon rod groups 104. Power supply 106 includes a controller 108 and a memory device 110.

In some embodiments, reactor 102 is a chemical vapor deposition (CVD) reactor. More specifically, in some embodiments, reactor 102 is a Siemens reactor. In other embodiments, reactor 102 may be any other suitable polysilicon reactor.

In the illustrated embodiment, each silicon rod group 104 includes a pair of series connected silicon rods 112. In other embodiments, silicon rod groups 104 may include any number of series connected silicon rods 112 (whether connected in pairs or not). In some embodiments, each silicon rod group 104 includes six silicon rods 112 connected in series. Current through the series connected silicon rods 112 (i.e., through each silicon rod group 104) is controlled as described herein. System 100 may include any suitable number of silicon rods 112, however configured and/or grouped. In various embodiments, system 100 includes 12, 18, 36, 48, 54, or 84 silicon rods 112.

In the exemplary embodiment, power supply 106 includes a plurality of power converters 114. Each power converter 114 is coupled to output power to a different silicon rod group 104. In other embodiments, power supply 106 may include a single power converter 114 coupled to all of the silicon rod groups 104. In some embodiments, power supply 106 may use one or more silicon controlled rectifiers with phase control to adjust the output current to one or more silicon rod group 104. In some embodiments, power supply 106 may include an inverter with adjustable DC output to control the output current to one or more silicon rod groups 104. Power converters 114 may have any suitable topology including, for example, buck, boost, flyback, forward, full-bridge, etc.

Controller 108 may be an analog controller, a digital controller, or a combination of analog and digital controllers/components. In embodiments in which controller 108 is a digital controller, controller 108 may include a processor, computer, etc. Although controller 108 is within power supply 106 in the exemplary embodiment, controller 108 may, additionally or alternatively, be external to power supply 106. For example, functions described as performed by controller 108 may be performed, completely or partially, by a separate controller, such as a system controller, for example.

Memory device 110 is one or more devices that enable information such as executable instructions and/or other data to be stored and retrieved. Memory device 110 may include one or more non-transitory computer readable media, such as, without limitation, dynamic random access memory (DRAM), static random access memory (SRAM), a solid state disk, and/or a hard disk. Memory device 110 may be configured to store, without limitation, computer-executable instructions, algorithms, results, and/or any other type of data. In some embodiments, memory device 110 is integrated in controller 108. In other embodiments memory device is external to controller 108 and/or power supply 106.

The exemplary embodiment provides control of surface temperature of silicon rod groups 104 in reactor 102 without relying on a temperature measurement of the silicon rods 112. Instead, power supply 106 uses a feedback control scheme based on the resistance of the silicon rod groups 104.

Joule heating is used to control the temperature of silicon rod groups 104. Joule heating is based on Joule's law, which may be expressed as:

Q=I²Rt [2]

where Q is the heat generated by a constant current I flowing through a conductor of electrical resistance R, for a time t.

Electrical resistance is a measurable quantity. For a uniform resistor, resistance is described by:

$$R = ρ \frac{L}{A} \qquad [ 3 ]$$

where R is the electrical resistance of the resistor, ρ is electrical resistivity of the material from which the resistor is constructed, L is the length of the resistor, and A is the cross-sectional area of the resistor. For a cylindrical solid, such as a silicon rod 112, having a diameter “d”, equation [3] can be reduced to:

$$R \approx ρ \frac{4 L}{π {d}^{2}} \qquad [ 4 ]$$

Resistivity of silicon rod groups 104, however, is not constant during a CVD process. As shown by equation [4], as the diameter of a silicon rod 112 increases, the resistance of the silicon rod 112 will decrease. Further, resistivity is a property describing mobility of electrons and depends strongly on temperature and, in the case of silicon rods 112, concentration of dopants in the silicon. Thus, resistance is not a constant value during a deposition process, but changes with the diameter of the silicon rods 112, the temperature gradient inside the silicon rods 112, and the purity of the deposited silicon (e.g., concentration of donors and acceptors).

For any given diameter of a silicon rod 112, resistance will vary with the temperature of the silicon rod 112. Specifically, resistance of a silicon rod 112 will decrease as temperature of the silicon rod 112 increases. Thus, for a given diameter silicon rod 112, a lower resistance will indicate a higher temperature and a higher resistance will indicate a lower temperature. Similarly, for a given diameter and resistance of a silicon rod 112, increasing the current through the rod 112 will increase the heat generated and increase the temperature of the rod 112 in accordance with equation [1]. Accordingly, resistance of silicon rod groups 104 may be used as feedback by the power supply 106 to monitor and/or control the temperature of silicon rods 112 in the CVD process.

To utilize resistance of silicon rod groups 104 as feedback for power supply 106, the resistance of silicon rod groups 104 must be determined. Electrical resistance of the silicon rod groups 104 may be determined using Ohm's law, as described by:

$$R = \frac{V}{I} \qquad [ 5 ]$$

where R is the electrical resistance of the silicon rod group 104, V is voltage applied across the silicon rod group 104, and I is the current through the silicon rod group 104. Thus, simply taking the ratio of the voltage applied to a particular silicon rod group 104 and the current through the particular silicon rod group 104 provides the resistance of that particular silicon rod group 104 at that particular moment.

The determined resistance is utilized to control the power output of the power supply 106, and thereby to control the temperature of the silicon rod groups 104, by comparing it with a resistance set point. For a given diameter of silicon rod groups 104, a determined resistance greater than the set point indicates the temperature of silicon rod groups 104 is less than desired, while a determined resistance less than the set point indicates the temperature of silicon rod groups 104 is greater than desired. Accordingly, power supply 106 may adjust the current supplied to silicon rod groups 104 to control the generated heat in silicon rod groups 104 to attempt to minimize the absolute value of the difference between the determined resistance and the set point.

As described above, the diameter of silicon rod groups 104 changes during the CVD process and the changing diameter of silicon rod groups 104 decreases the resistance of silicon rod groups 104. Accordingly, the resistance set point should be varied during the process to account for the varying diameter.

In the exemplary embodiment, the resistance set point is a set point curve. The set point curve may be derived by statistical analysis of existing CVD processes. The set point curve may be adjusted as additional data is acquired. Further, control based on resistance is self regulating within a certain range. If the resistance set point is set too low, silicon rod groups 104 will experience high surface temperatures. This high temperature will speed up the deposition rate and the diameter of silicon rod groups 104 will increase more rapidly until the set point is reached. In contrast, if the set point is too high, the surface temperature of silicon rod groups 104 will be too low, which may slow down deposition rate and result in increased resistance. In other embodiments, a resistance set point is derived from the exact diameter of the silicon rod groups 104 at each moment of the deposition process and an exact formula for resistivity as a function of temperature. In other embodiments, the resistance set point may vary as a function of time. In still other embodiments the resistance set point is chosen according to another suitable set point variation law.

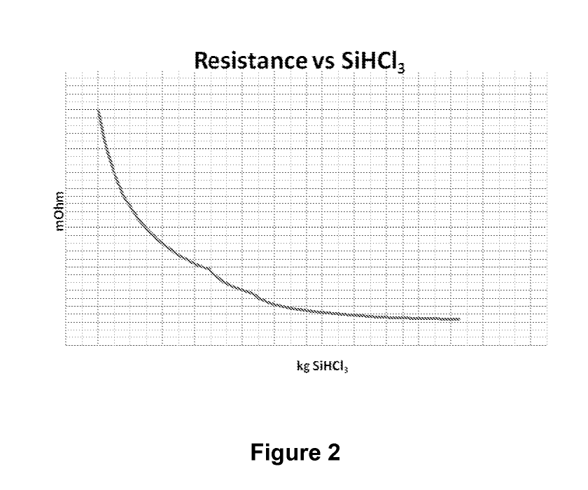

FIG. 2 graphically illustrates an exemplary statistically derived set point curve. The resistance set point is plotted as a function of the amount of trichlorosilane (TCS) that has entered reactor 102 from the beginning of a CVD process. At the beginning of the run, i.e. when little TCS has been fed into reactor 102, silicon rod groups 104 are rather small and the cross sectional area tends to increase quickly percentagewise. At the end of the run, though the deposition rate in terms of kg/hr may be higher, the increment in cross sectional area of silicon rod groups 104 is more limited. The amount of silicon deposited on any one silicon rod group 104 during the CVD process may be approximated as a proportional share of the total quantity of TCS fed to reactor 102. Accordingly, the diameter of silicon rod groups 104, and thus expected resistance at a desired temperature, may be estimated for any time in the CVD process as a function of a proportional amount of the total amount of TCS that has entered reactor 102 during the CVD process. Thus, in an example embodiment, the resistance set point is described by:

$$R = {A ( ( {\int }_{0}^{t} {m}_{{SiHCl}_{3}} d t ) - B )}^{- C} \qquad [ 6 ]$$

where R is the resistance set point, A, B and C are constant values, t is time, and m_{SiHCl3} is the flow rate of TCS.

In one example embodiment, the values of A, B and C in equation [6] for three levels of total amount of TCS fed to reactor 102 are:

| kg TCS | A | B | C | R (mOhm/m) |
|---|---|---|---|---|
| 10000 | 112000 | 0 | 0.91 | 25.65 |
| 50000 | 273 | 39000 | 0.32 | 13.89 |
| 70000 | 13.4 | 63000 | 0.08 | 6.599 |

where R is the resistance set point, i.e. the expected resistance corresponding to the proper surface temperature for an individual silicon rod per unit of length.

In some embodiments, the power to each silicon rod group 104 may be separately controlled using the resistance of each silicon rod group 104 and the appropriate resistance set point. Particularly in embodiments in which reactor 102 includes greater numbers of silicon rods 112, uneven operating conditions inside reactor 102 may be common. Different silicon rod groups 104 in reactor 102 may be subjected to different flow fields and gas mixture compositions. Controlling power to individual silicon rod groups 104 permits relatively homogeneous growth among the individual silicon rod groups 104 despite the different conditions experienced by silicon rod groups 104. Further, by controlling power flow to silicon rod groups 104 in this manner, the CVD process may continue if one or more silicon rod groups 104 are shut down.

Resistance based control and systems as described herein, may achieve superior results to some known methods of control. For example, increased performance in terms of deposition rate and morphology may be achieved together with reduced energy consumption. Unlike some known methods, the control scheme described herein does not rely on proper temperature measurement, which is affected by silicon dust, calibration, gas turbulence, etc. and may be difficult and unstable. Further, in some known methods and systems, temperature is measured only at one or few spots within the reactor. In such methods, conditions at the location of measurement drive the process control affecting all the rods regardless of the conditions of any individual rod. Moreover, with some known temperature control systems, if a reference rod shut down, the entire reactor may stop and/or the reactor may be run with no feedback control.

Some embodiments involve the use of one or more electronic or computing devices. Such devices typically include a processor or controller, such as a general purpose central processing unit (CPU), a graphics processing unit (GPU), a microcontroller, a reduced instruction set computer (RISC) processor, an application specific integrated circuit (ASIC), a programmable logic circuit (PLC), and/or any other circuit or processor capable of executing the functions described herein. The methods described herein may be encoded as executable instructions embodied in a computer readable medium, including, without limitation, a storage device and/or a memory device. Such instructions, when executed by a processor, cause the processor to perform at least a portion of the methods described herein. The above examples are exemplary only, and thus are not intended to limit in any way the definition and/or meaning of the term processor.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

The description of the different advantageous embodiments has been presented for purposes of illustration and description, and is not intended to be exhaustive or limited to the embodiments in the form disclosed. Many modifications and variations will be apparent to those of ordinary skill in the art. Further, different advantageous embodiments may provide different advantages as compared to other advantageous embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

An element or step recited in the singular and proceeded with the word “a” or “an” should be understood as not excluding plural elements or steps unless such exclusion is explicitly recited. Moreover, references to “one embodiment” of the present invention and/or the “exemplary embodiment” are not intended to be interpreted as excluding the existence of additional embodiments that also incorporate the recited features.

What is claimed is:

1. A method of controlling a surface temperature of at least one silicon rod in a chemical vapor deposition (CVD) reactor during a CVD process, the method comprising:
determining an electrical resistance of the at least one silicon rod;
comparing the resistance to a set point to determine a difference; and
controlling a power supply coupled to the at least one silicon rod to minimize an absolute value of the difference according to a feedback process control scheme.

2. A method in accordance with claim 1, wherein comparing the resistance to a set point comprises comparing the resistance to a variable set point, wherein the set point is variable as a function of an amount of reactant input to the reactor during the CVD process.

3. A method in accordance with claim 2, wherein the variable set point comprises a set point curve.

4. A method in accordance with claim 3, further comprising analyzing data from at least one completed CVD process to derive the set point curve.

5. A method in accordance with claim 2 wherein:
determining a resistance of at least one silicon rod comprises determining a first resistance of a first group of silicon rods and determining a second resistance of a second group of silicon rods;
comparing the resistance to a variable set point to determine a difference comprises comparing the first resistance to the variable set point to determine a first difference and comparing the second resistance to the variable set point to determine a second difference; and
controlling a power supply coupled to the at least one silicon rod comprises controlling the power supply to minimize an absolute value of the first difference and to minimize an absolute value of the second difference.

6. A method in accordance with claim 5 wherein:
the first group of silicon rods comprises six silicon rods connected in series; and
the second group of silicon rods comprises six silicon rods connected in series.

7. A method in accordance with claim 1, wherein the CVD reactor is a Siemens reactor.

8. A system comprising:
a chemical vapor deposition (CVD) reactor;
a plurality of groups of silicon rods coupled within the CVD reactor;
a power supply coupled to provide power to the plurality of groups of silicon rods; and
a controller configured to:
determine a first resistance of a first group of silicon rods of the plurality of groups of silicon rods;
compare the first resistance to a set point to determine a first difference; and
control the power supply to minimize an absolute value of the first difference.

9. A system in accordance with claim 8, wherein the controller is configured to compare the first resistance to a variable set point to determine the first difference, and wherein the variable set point is variable as a function of an amount of reactant input to the reactor during a CVD process.

10. A system in accordance with claim 9, wherein the controller is further configured to:
determine a second resistance of a second group of silicon rods of the plurality of groups of silicon rods;
compare the second resistance to the variable set point to determine a second difference; and
control the power supply to minimize an absolute value of the second difference.

11. A system in accordance with claim 8, wherein the plurality of groups of silicon rods coupled within the CVD reactor comprises twenty or more silicon rods.

12. A system in accordance with claim 8, wherein each group of the plurality of groups of silicon rods comprises six silicon rods.

13. A system in accordance with claim 12, wherein the six silicon rods of each group of the plurality of groups of silicon rods are connected in series.

14. A system in accordance with claim 8, wherein the CVD reactor is a Siemens reactor.

15. A system in accordance with claim 8, wherein the plurality of groups of silicon rods coupled within the CVD reactor comprises fifty-four silicon rods.

16. A system in accordance with claim 15, wherein each group of the plurality of groups of silicon rods comprises six silicon rods.

17. A system in accordance with claim 8, wherein the power supply comprises a plurality of power converters, each power converter coupled to supply power to a different group of the plurality of groups of silicon rods.

18. A system in accordance with claim 17, wherein the plurality of power converters comprises a first power converter coupled to the first group of silicon rods to provide power to the first group of silicon rods, and wherein the controller is configured to control the power supply to minimize an absolute value of the first difference by controlling the first power converter.
